(19) United States
(12) Patent Application Publication
(10) Pub. No.: US 2026/0123298 A1
(43) Pub. Date: Apr. 30, 2026

(54) FACET TRAPPING FOR EPITAXIAL GROWTH

(71) Applicant: TEXAS INSTRUMENTS INCORPORATED, Dallas, TX (US)

(72) Inventors: Gordon Nielsen, Cedar Hills, UT (US); Jonathan Lane, Sandy, UT (US); Matthew Willford, Lehi, UT (US); SK Saiful Islam, Lehi, UT (US)

(21) Appl. No.: 18/930,154

(22) Filed: Oct. 29, 2024

(51) Int. Cl. H01L 21/02; C30B 25/04; H01L 21/311; H01L 29/66

(52) U.S. Cl. CPC H10P 14/276; C30B 25/04; H10D 10/01; H10P 50/283

(57) ABSTRACT

The present disclosure generally relates to semiconductor processing including facet trapping for an epitaxial growth process. In an example, a dielectric layer is formed over a first semiconductor material that includes a monocrystalline surface. A recess is formed in the dielectric layer and is defined by a recess sidewall. A spacer layer is formed conformally in the recess. A sidewall spacer is formed from the spacer layer and is along the recess sidewall. An opening is formed through the dielectric layer to the monocrystalline surface. Forming the opening includes etching the dielectric layer under the sidewall spacer. The opening is defined by an opening sidewall corresponding to the recess sidewall and a cavity in the dielectric layer. The cavity is at the monocrystalline surface and under the opening sidewall. A second semiconductor material is formed on the monocrystalline surface and in the opening.

### BACKGROUND

Integrated circuits may include bipolar junction transistors (BJTs). BJTs may be desirable for their high gain characteristics to satisfy high performance and high current drive needs. Scaling of devices in an integrated circuit to smaller nodes typically requires novel approaches to semiconductor processing for fabricating those devices.

### SUMMARY

An example described herein is a method. A dielectric layer is formed over a first semiconductor material. The first semiconductor material includes a monocrystalline surface. A recess is formed in the dielectric layer. The recess is defined at least in part by a recess sidewall of the dielectric layer. A spacer layer is formed conformally in the recess. A sidewall spacer in the recess is formed from the spacer layer. The sidewall spacer is along the recess sidewall. An opening is formed through the dielectric layer to the monocrystalline surface. Forming the opening includes etching the dielectric layer under the sidewall spacer. The opening is defined at least in part by an opening sidewall of the dielectric layer and a cavity in the dielectric layer. The opening sidewall corresponds to the recess sidewall. The cavity is at the monocrystalline surface and under the opening sidewall. A second semiconductor material is formed over the first semiconductor material and on the monocrystalline surface. The second semiconductor material is at least partially in the opening through the dielectric layer.

Another example is a method. A pedestal dielectric stack is formed over a semiconductor substrate. A recess is formed in the pedestal dielectric stack. The recess is defined at least in part by a recess sidewall of the pedestal dielectric stack. A spacer layer is formed over the pedestal dielectric stack and conformally in the recess. The spacer layer is anisotropically etched to form a sidewall spacer on the recess sidewall. The pedestal dielectric stack is isotropically etched through the recess. Isotropically etching the pedestal dielectric stack forms an opening through the pedestal dielectric stack to the semiconductor substrate. The opening is defined at least in part by an opening sidewall of the pedestal dielectric stack and a cavity in the pedestal dielectric stack under the opening sidewall. The opening sidewall corresponds to the recess sidewall. A bipolar junction transistor (BJT) is formed on the semiconductor substrate. At least a portion of the BJT is in the opening and on the semiconductor substrate.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIGS. 1 through 7 are respective cross-sectional views of a semiconductor structure in intermediate stages of manufacturing according to some examples.

FIGS. 8 through 27 are respective cross-sectional views of a semiconductor device in intermediate stages of manufacturing according to some examples.

FIGS. 12A, 13A, 14A, 15A, and 16A are expanded views of portions of the cross-sectional views of FIGS. 12, 13, 14, 15, and 16, respectively.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing including facet trapping for an epitaxial growth process. Some examples include a semiconductor device that include a first semiconductor material, a dielectric layer, and a second semiconductor material. The first semiconductor material includes a monocrystalline surface. The dielectric layer is over the first semiconductor material and has an opening to the monocrystalline surface. The opening through the dielectric layer is defined at least in part by a sidewall of the dielectric layer and a cavity in the dielectric layer. The cavity is at the monocrystalline surface of the first semiconductor material and is under the sidewall of the dielectric layer. The opening may be formed by forming a recess in the dielectric layer, conformally forming a spacer layer in the recess, forming a sidewall spacer from the spacer layer along a recess sidewall (e.g., by an aniostropic etch), and etching (e.g., by an isotropic etch) the dielectric layer under the sidewall spacer. The second semiconductor material is over the first semiconductor material and is on the monocrystalline surface of the first semiconductor material. The second semiconductor material is at least partially in the opening through the dielectric layer.

The second semiconductor material may be formed using epitaxial growth. During epitaxial growth of the second semiconductor material, a facet may be formed by the second semiconductor material. The cavity in the dielectric layer may be configured in a way that the facet is trapped by the cavity such that propagation of the facet during subsequent epitaxial growth is arrested. Arresting propagation of the facet may permit a plane of the monocrystalline surface to more easily be replicated in the second semiconductor material. Further, trapping a facet by the cavity during epitaxial growth may permit the semiconductor substrate (e.g., wafer) to be rotated during semiconductor processing at an angle that is more preferential for other aspects, such as for forming embedded stressors (e.g., embedded silicon germanium (SiGe)) in complementary metal-oxide-semiconductor (CMOS) field effect transistors (FETs). Other benefits and advantages may be achieved.

Various examples are described subsequently. Although the specific examples may illustrate various aspects of the above generally described features, examples may incorporate any combination of the above generally described features (which are described in more detail in examples below).

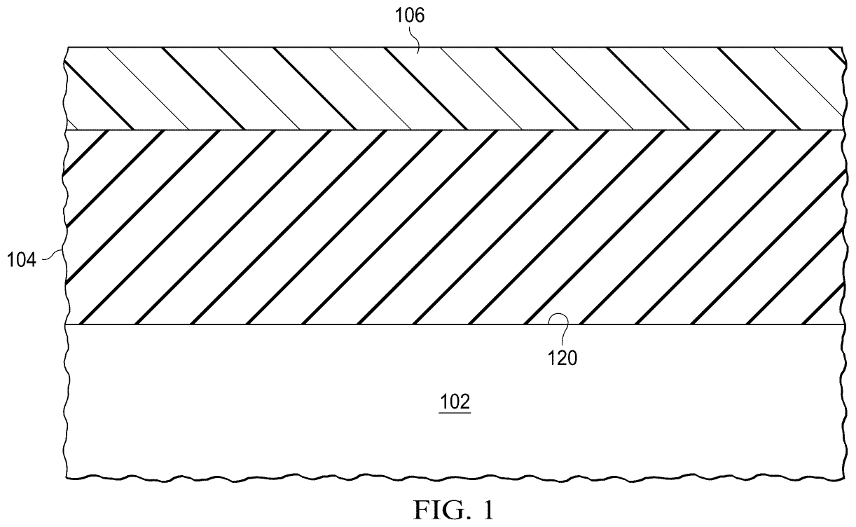

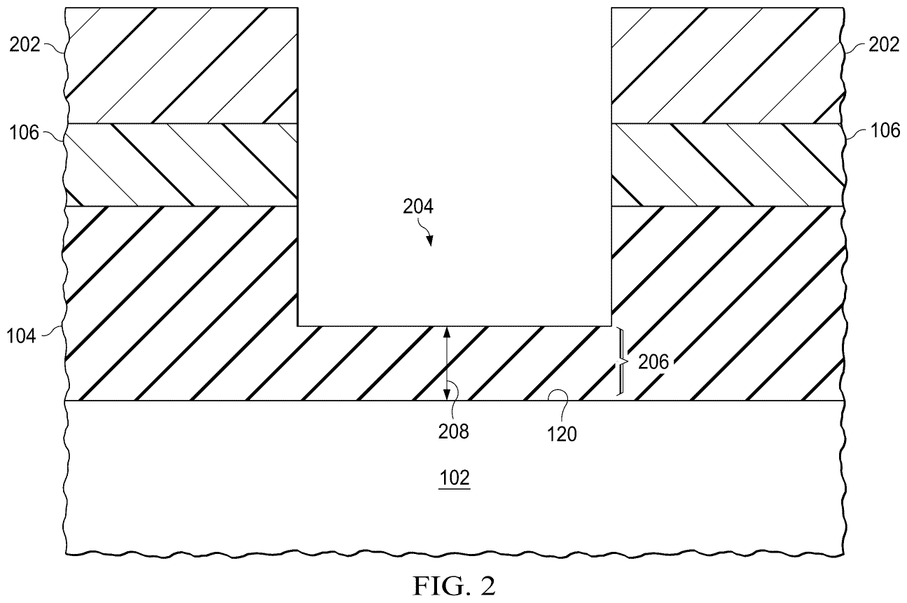

FIGS. 1 through 7 are respective cross-sectional views of a semiconductor structure in intermediate stages of manufacturing according to some examples. Referring to FIG. 1, a dielectric layer 104 is formed over a semiconductor substrate 102, and a hardmask layer 106 is formed over the dielectric layer 104. The semiconductor substrate 102 includes a semiconductor material that is monocrystalline. The semiconductor substrate 102 has an upper surface 120 that is a monocrystalline surface of the monocrystalline semiconductor material. The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer epitaxially grown on the support substrate. In some examples, the semiconductor substrate 102 is or includes a silicon substrate (which may be singulated from a bulk silicon wafer at the conclusion of semiconductor processing). In further examples, the semiconductor substrate 102 includes a silicon substrate with an epitaxial silicon layer grown thereon. In some examples, the semiconductor material is or includes silicon (Si), silicon germanium (SiGe), gallium arsenide (GaAs), gallium nitride (GaN), the like, or a combination thereof. In some examples, the monocrystalline semiconductor material is silicon, and the upper surface 120 is a (100) plane of monocrystalline silicon.

The dielectric layer 104 may be or include one dielectric layer or multiple dielectric sub-layers. For example, the dielectric layer 104 may be or include silicon oxide. In some examples, the dielectric layer 104 is silicon oxide formed by in situ steam generation (ISSG) oxidation. In some examples, the dielectric layer 104 is silicon oxide formed by a high temperature oxide (HTO) low pressure chemical vapor deposition (LPCVD) or the like. In some examples, the dielectric layer 104 is silicon oxide (e.g., a tetraethyl orthosilicate (TEOS) oxide) deposited by chemical vapor deposition (CVD). In some examples, the dielectric layer 104 includes a first sub-layer of a silicon oxide (e.g., silicon oxide formed by ISSG oxidation), and a second sub-layer of silicon oxide (e.g., an oxide deposited by HTO-LPCVD) over the first sub-layer, and a third sub-layer of silicon oxide (e.g., a TEOS oxide deposited by CVD) over the second sub-layer. In such examples, the first and second sub-layers have a first etch rate(s), and the second sub-layer has a second etch rate greater than the first etch rate(s). In other examples, the dielectric layer 104 may be or include different dielectric materials, such as silicon nitride, silicon oxynitride, silicon carbon nitride, the like, or a combination thereof.

The hardmask layer 106 may be or include a dielectric layer. For example, the hardmask layer 106 may be or include silicon nitride. In some examples, the hardmask layer 106 is silicon nitride deposited by CVD. The hardmask layer 106 may have etch selectivity with respect to the dielectric layer 104.

Referring to FIG. 2, a photoresist 202 is formed over the hardmask layer 106 and patterned with an opening through the photoresist 202. For example, the photoresist 202 is deposited (e.g., by spin-on) over and/or on the hardmask layer 106 and is patterned to have the opening using photolithography. Then, a recess 204 is formed through the hardmask layer 106 and in the dielectric layer 104 through the opening of the photoresist 202. Using the patterned photoresist 202 as a mask, an etch process, such as an anisotropic etch like a reactive ion etch (RIE), is performed to etch the hardmask layer 106 and the dielectric layer 104 and to form the recess 204 through the hardmask layer 106 and in the dielectric layer 104. The recess 204 is defined by substantially vertical sidewalls and a bottom surface formed by a lateral surface of the dielectric layer 104. A portion 206 of the dielectric layer 104 remains between the recess 204 (e.g., from the bottom surface of the recess 204) and the upper surface 120 of the semiconductor substrate 102. The portion 206 of the dielectric layer 104 has a thickness 208 (e.g., from the bottom surface of the recess 204 to the upper surface 120 of the semiconductor substrate 102). The thickness 208 subsequently defines, at least in part, a dimension of a facet trap (e.g., a cavity) formed in the dielectric layer 104. The thickness 208 may be achieved by tuning the duration of the etch process that forms the recess 204, by an etch selectivity between different sub-layers of the dielectric layer 104, and/or by another mechanism. After forming the recess 204, the photoresist 202 is removed. The photoresist 202 may be removed using an ashing, for example.

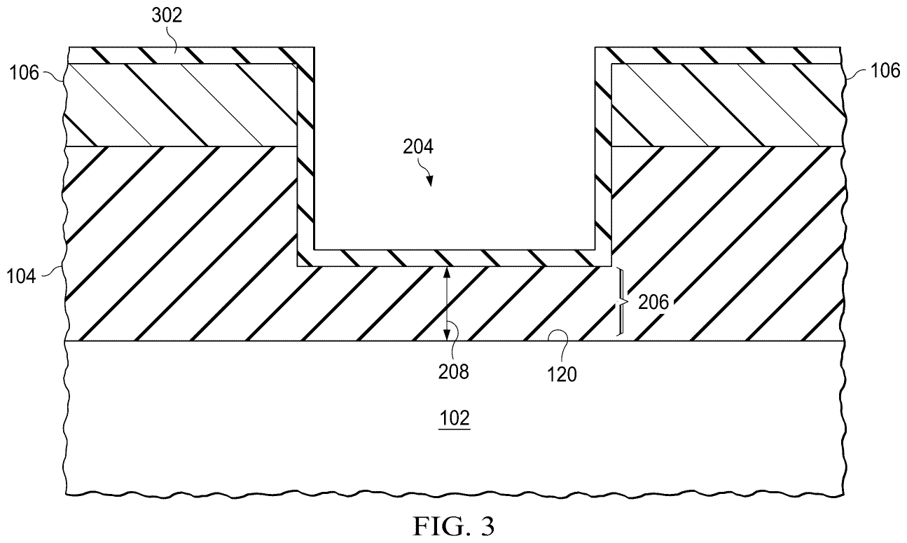

Referring to FIG. 3, a sidewall spacer layer 302 is conformally formed over the hardmask layer 106 and in the recess 204. More specifically, the sidewall spacer layer 302 is formed along respective sidewalls of the recess 204 in the hardmask layer 106 and dielectric layer 104, on a bottom surface of the recess 204 in the dielectric layer 104, and on an upper surface of the hardmask layer 106. The sidewall spacer layer 302 may be or include any dielectric material that has an etch rate to an etchant (e.g., that is used to etch a cavity as described below) that is less than an etch rate to the etchant of the dielectric layer 104. In some examples, a thickness of the sidewall spacer layer 302 may be determined based on the etch rates to the etchant of the sidewall spacer layer 302 and the dielectric layer 104 and a target profile of a cavity to be formed using an etch process that includes the etchant, as detailed subsequently. In some examples, the thickness of the sidewall spacer layer 302 is in a range from 80 Å to 120 Å. In some examples, the sidewall spacer layer 302 is or includes silicon nitride and may be deposited by atomic layer deposition (ALD), plasma enhanced CVD (PECVD), or the like.

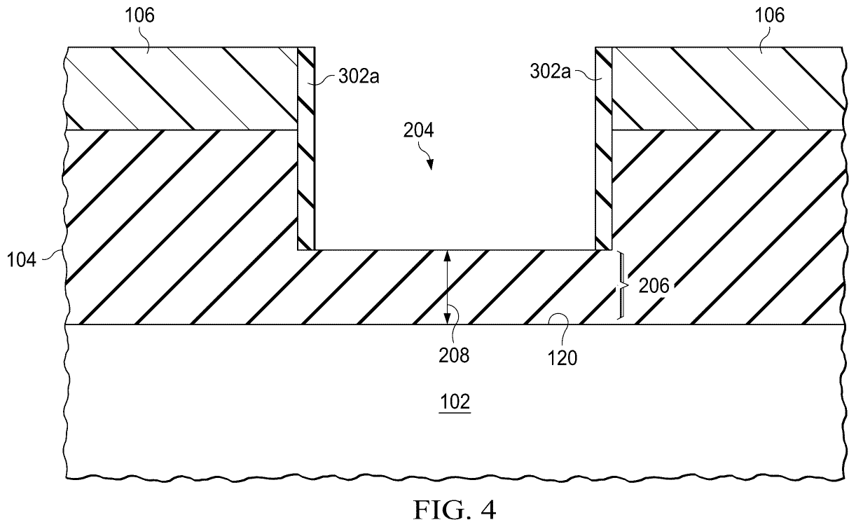

Referring to FIG. 4, an anisotropic etch is performed to remove horizontal portions of the sidewall spacer layer 302 such that vertical sidewall spacers 302a remain on respective sidewalls of the recess 204. The anisotropic etch may be an RIE, for example. The anisotropic etch removes the sidewall spacer layer 302 from the upper surface of the hardmask layer 106 and from the bottom surface of the recess 204. Although not illustrated some of the hardmask layer 106 may be consumed by the anisotropic etch, such as when the sidewall spacer layer 302 is a same material as the hardmask layer 106. In some examples, an upper portion of the hardmask layer 106 may be oxidized, such as by an ashing when the photoresist 202 is removed, which may form an etch stopping mechanism to the anisotropic etch.

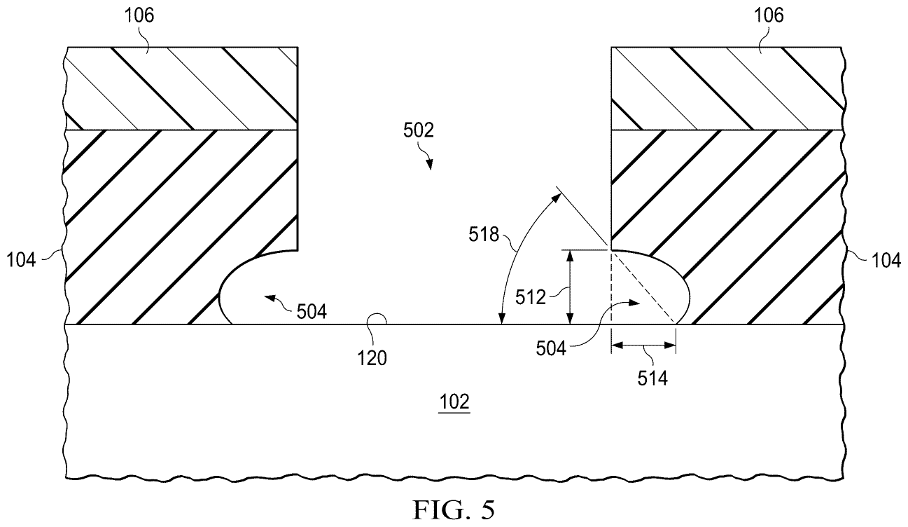

Referring to FIG. 5, an etch process is performed to remove the remaining portion 206 of the dielectric layer 104 and to undercut in the dielectric layer 104 under the sidewall spacers 302a. The etch process also removes the sidewall spacers 302a from the sidewalls. The etch process forms an opening 502 through the dielectric layer 104 and hardmask layer 106 that is defined in part by a cavity 504. The etch may be an isotropic etch, which may further be a wet etch. The etch process uses an etchant. For example, when the dielectric layer 104 is silicon oxide and the sidewall spacers 302a are silicon nitride, the etchant may include hydrofluoric (HF) acid, and the etch process may be or include a buffered oxide etch (BOE), a dilute hydrofluoric (dHF) acid, or the like.

The etch process consumes (and hence, removes) the sidewall spacers 302a as the dielectric layer 104 is etched (e.g., to remove the remaining portion 206 and undercut the sidewall spacers 302a into the dielectric layer 104). Because the sidewall spacers 302a have a lower etch rate to the etchant used in the etch process than the etch rate of the dielectric layer 104, the cavity 504 is formed in the dielectric layer 104 undercutting the sidewall spacers 302a. Before the sidewall spacers 302a are completely consumed, the sidewall spacers 302a prevent the sidewalls of the dielectric layer 104 from being etched where the sidewall spacers 302a cover the sidewalls. The etch removes the remaining portion 206 of the dielectric layer 104 in a direction from the bottom surface of the recess 204 to expose the upper surface 120 of the semiconductor substrate 102. As the etch is performed, cavities 504 are isotropically formed in the dielectric layer 104 undercutting the sidewall spacers 302a. The cavities 504 are formed to and expose the upper surface 120 of the semiconductor substrate 102. The etch forms the opening 502 through the dielectric layer 104, and the opening 502 is laterally defined by sidewalls corresponding to the recess 204 and cavities 504. As indicated above, the thickness of the sidewall spacers 302a and materials of the dielectric layer 104 and the sidewall spacers 302a may be selected such that the etch rates of the materials to the etchant forms the cavities 504 with a target profile while also removing the sidewall spacers 302a. The profile of the cavities 504 may be achieved as the sidewall spacers 302a are completely consumed without further etching the sidewalls of the dielectric layer 104 from which the sidewall spacers 302a are removed, in some examples. In other examples, the profile of the cavities 504 may be achieved after the sidewall spacers 302a are completely consumed and with etching the sidewalls of the dielectric layer 104 from which the sidewall spacers 302a are removed.

The cavities 504 may result in the opening 502 avoiding having lateral footings of the dielectric layer 104 at the upper surface 120 of the semiconductor substrate 102 that would laterally constrict the opening 502 more than the sidewalls of the opening 502. Avoiding such footings may remove a mechanism that induces or influences facet formation during subsequent epitaxial growth—e.g., on the exposed upper surface 120 of the semiconductor substrate 102.

A cavity 504, as illustrated, is defined by a curved surface of the dielectric layer 104. The cavity 504 has a vertical dimension 512 and a lateral dimension 514. The vertical dimension 512 is from the upper surface 120 of the semiconductor substrate 102 orthogonally to an intersection point where the curved surface of the cavity 504 meets the corresponding sidewall of the dielectric layer 104 (which corresponds to a respective sidewall of the recess 204). The vertical dimension 512 may be equal to or greater than the thickness 208 of the remaining portion 206 of the dielectric layer 104 that is etched. The lateral dimension 514 is from the corresponding sidewall of the dielectric layer 104 (which corresponds to a respective sidewall of the recess 204) orthogonally to an intersection point where the curved surface of the cavity 504 meets the upper surface 120 of the semiconductor substrate 102. The vertical dimension 512 and lateral dimension 514 form an angle 518 between the upper surface 120 of the semiconductor substrate 102 and a line from the intersection point where the curved surface of the cavity 504 meets the upper surface 120 to the intersection point where the curved surface of the cavity 504 meets the corresponding sidewall of the dielectric layer 104. The angle 518 is laterally interior to the opening 502. The angle 518 is the inverse tangent of the ratio of the vertical dimension 512 to the lateral dimension 514

$$( e . g . , {θ}_{518} = {tan}^{- 1} ( \frac{{V}_{512}}{{L}_{514}} ) ,$$

where θ₅₁₈ is the angle 518, V₅₁₂ is the vertical dimension 512, and L₅₁₄ is the lateral dimension 514). In some examples, the lateral dimension 514 is equal to or greater than 10 nm, such as equal to or greater than 20 nm.

The angle 518 (and hence, the ratio of the vertical dimension 512 to the lateral dimension 514) is such that a facet formed in a subsequent epitaxial growth is trapped in the cavity 504. For example, when the upper surface 120 is a (100) plane of monocrystalline silicon and silicon is epitaxially grown on the upper surface 120, the silicon epitaxially grown may have a (111) plane facet. In such an example, the angle 518 may be equal to or less than 54.7° (e.g., equal to or less than) 54°. The ratio of the vertical dimension 512 to the lateral dimension 514 may be equal to or less than 1.376. With such an angle 518, the (111) plane facet may intersect the curved surface of the cavity 504 when the silicon is grown to sufficient thickness, which may cause the (111) plane facet to arrest further propagation in subsequent epitaxial growth. Hence, the cavity 504 may be considered a facet trap. The angle 518 may be another angle depending on, e.g., which plane of a facet may be trapped by the cavity 504.

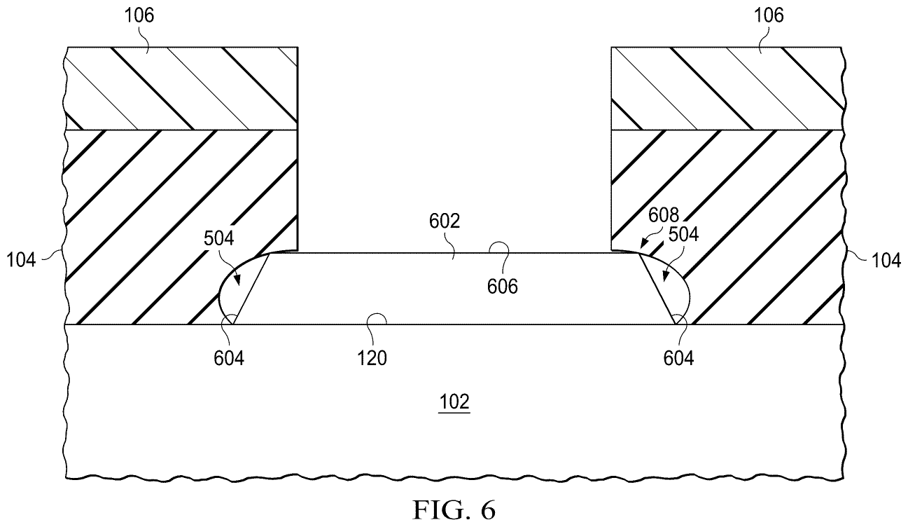

Referring to FIG. 6, an epitaxial layer 602 is epitaxially grown to a thickness sufficient such that a facet 604 of the epitaxial layer 602 is trapped in the cavity 504. The epitaxial layer 602 may be any semiconductor material and may be monocrystalline. In some examples, the epitaxial layer 602 is silicon. The epitaxial growth process may be a CVD process, such as a low pressure CVD (LPCVD), reduced pressure CVD (RPCVD), metal organic CVD (MOCVD), or the like. The epitaxial growth of the epitaxial layer 602 forms a surface 606 that replicates the upper surface 120 of the semiconductor surface and forms the facet 604. For example, the surface 606 of the epitaxial layer 602 may be a (100) plane when the upper surface 120 of the semiconductor substrate 102 is a (100) plane, and the facet 604 may be in a (111) plane. The facet 604 meets the curved surface of the cavity 504 at an intersection point 608. The curved surface (e.g., upper surface, ceiling) of the cavity 504 meeting the facet 604 arrests the facet 604 and prevents the facet 604 from further propagation. Hence, the surface 606 may continue to be replicated vertically in subsequent epitaxial growth without the facet 604 meeting and laterally limiting replication of the surface 606.

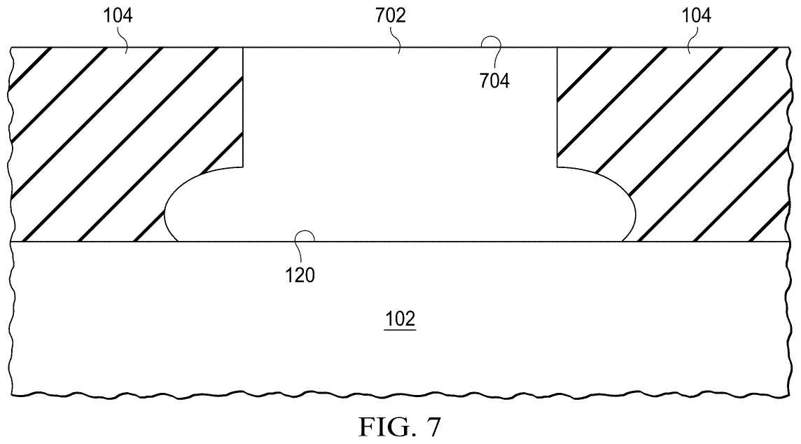

Referring to FIG. 7, epitaxial growth of the epitaxial layer 602 continues such that an epitaxial layer 702 is formed. The epitaxial layer 702 has a surface 704 that replicates the surface 606 in FIG. 6 and, hence, replicates the upper surface 120 of the semiconductor substrate 102. Although the cavities 504 are illustrated in FIG. 7 as being filled by the epitaxial layer 702, in some examples, a void may be formed in a cavity 504.

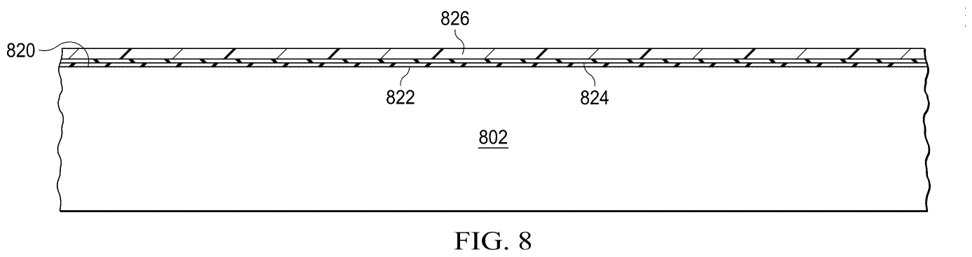

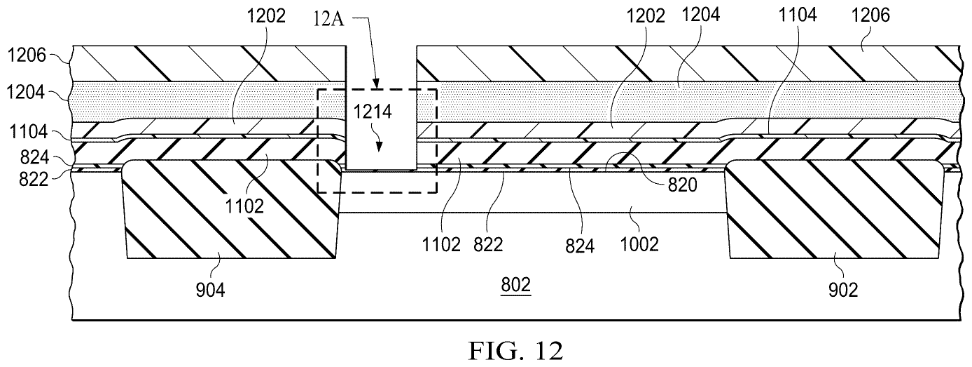

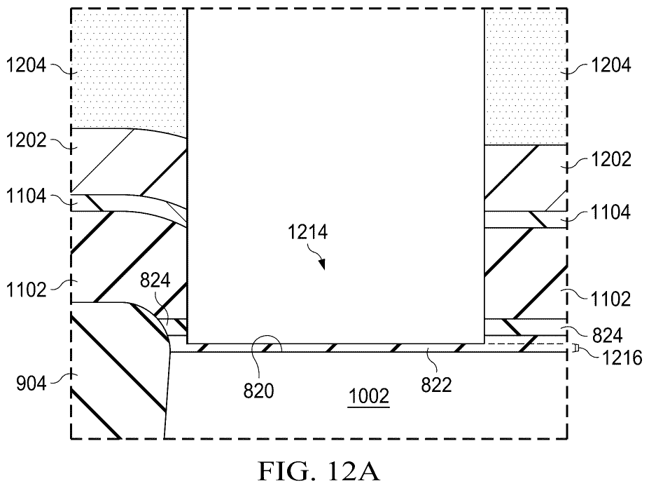

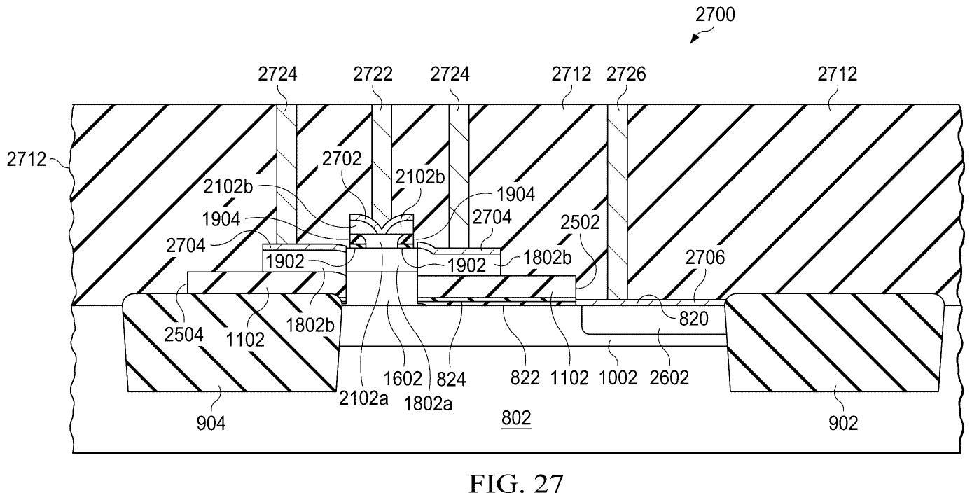

FIGS. 8 through 27 are respective cross-sectional views of a semiconductor device in intermediate stages of manufacturing according to some examples. The method illustrated in these figures forms the semiconductor device 2700 (e.g., a bipolar junction transistor (BJT)) of FIG. 27. FIGS. 12A, 13A, 14A, 15A, and 16A are expanded views of portions of the cross-sectional views of FIGS. 12, 13, 14, 15, and 16, respectively. The manufacturing method described above with respect to FIGS. 1 through 7 is implemented in the manufacturing illustrated in FIGS. 8 through 27 as referenced subsequently.

Referring to FIG. 8, a semiconductor substrate 802 is provided. The semiconductor substrate 802 is like the semiconductor substrate 102 of FIG. 1 described above. The semiconductor substrate 802 has an upper surface 820 in and/or on which devices (e.g., the BJT) are formed. In the illustrated example, the semiconductor material (e.g., silicon) of the semiconductor substrate 802 is p-type doped with a p-type dopant. In some examples, the semiconductor substrate 802 is p-type doped with a p-type dopant (e.g., boron (B)) with a concentration in a range from 1×10¹⁴ cm⁻³ to 1×10¹⁵ cm⁻³. Another dopant type and/or other doping concentrations may be implemented.

A first pedestal dielectric sub-layer 822 is formed over and on the upper surface 820 of the semiconductor substrate 802. In some examples, the first pedestal dielectric sub-layer 822 is or includes silicon oxide, which may be formed by ISSG oxidation. The first pedestal dielectric sub-layer 822 may also be, for example, a pad oxide layer. Another dielectric material and/or formation or deposition technique may be implemented.

A second pedestal dielectric sub-layer 824 is formed over and on the first pedestal dielectric sub-layer 822. In some examples, the second pedestal dielectric sub-layer 824 is or includes silicon oxide, which may be deposited by HTO-LPCVD. Another dielectric material and/or formation or deposition technique may be implemented.

A hardmask layer 826 is formed over and on the second pedestal dielectric sub-layer 824. In some examples, the hardmask layer 826 is or includes silicon nitride, which may be deposited by CVD. Any dielectric material that may be selectively etched relative to the second pedestal dielectric sub-layer 824 and/or the first pedestal dielectric sub-layer 822 may be implemented for the hardmask layer 826, and any appropriate deposition process may be implemented to form the hardmask layer 826.

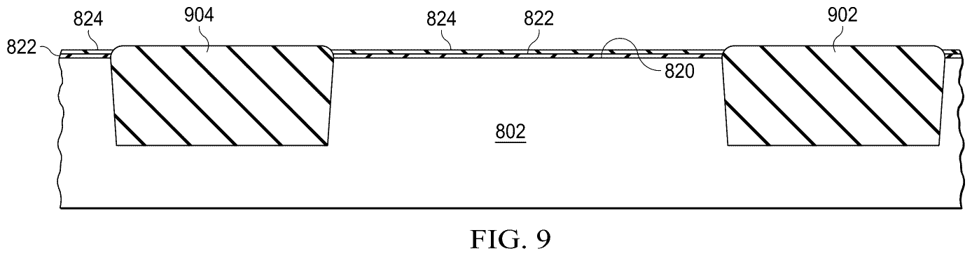

Referring to FIG. 9, isolation structures 902, 904 are formed in the semiconductor substrate 802. In the illustrated example, the isolation structures 902, 904 are shallow trench isolation structures (STIs) extending from the upper surface 820 of the semiconductor substrate 802 into the semiconductor substrate 802. As illustrated, the isolation structures 902, 904 are also through the first pedestal dielectric sub-layer 822 and the second pedestal dielectric sub-layer 824 and are raised above the upper surface 820 of the semiconductor substrate 802. The isolation structures 902, 904 may include, for example, a liner layer, such as including silicon oxide or silicon nitride, conformally along surfaces of a respective trench through the first pedestal dielectric sub-layer 822 and second pedestal dielectric sub-layer 824 and in the semiconductor substrate 802 and a fill isolation material, such as silicon oxide, over and on the liner layer.

To form the isolation structures 902, 904, trenches are formed through the first pedestal dielectric sub-layer 822 and second pedestal dielectric sub-layer 824 and in the semiconductor substrate 802. The trenches may be formed by patterning the hardmask layer 826, such as by using photolithography and an etching process (e.g., RIE). The trenches are etched, such as by RIE, through the first pedestal dielectric sub-layer 822 and second pedestal dielectric sub-layer 824 and in the semiconductor substrate 802 using the patterned hardmask layer 826 as a mask. The liner layer may then be conformally deposited in the recesses or trenches and over the patterned hardmask layer 826, such as by plasma enhanced CVD (PECVD) or formed on exposed surfaces of the recesses or trenches (e.g., by an oxidation process), and the fill isolation material may be deposited over the liner layer, such as by high aspect ratio CVD (HAR-CVD), flowable CVD (FCVD), or the like. Excess fill isolation material and liner layer may be removed from over the hardmask layer 826 by a planarization process, such as a chemical mechanical polish (CMP). The hardmask layer 826 may then be removed by an etch selective to the hardmask layer 826, which may be a wet etch process. In other examples, the isolation structures 902, 904 may be field oxide structures, such as local oxidation of silicon (LOCOS) structures, at the upper surface 820 of the semiconductor substrate 802, which may be formed using a LOCOS process.

The isolation structures 902, 904 laterally defines an area (e.g., an active area) of the upper surface 820 of the semiconductor substrate 802 on which the BJT is to be formed. The isolation structures 902, 904 together laterally encircle or encompass the active area of the upper surface 820 of the semiconductor substrate 802 on which the BJT is to be formed. As indicated subsequently, an active portion (e.g., a base layer) of the BJT extends laterally beyond the active area of the upper surface 820 of the semiconductor substrate 802 on which the BJT is formed and over the isolation structure 904.

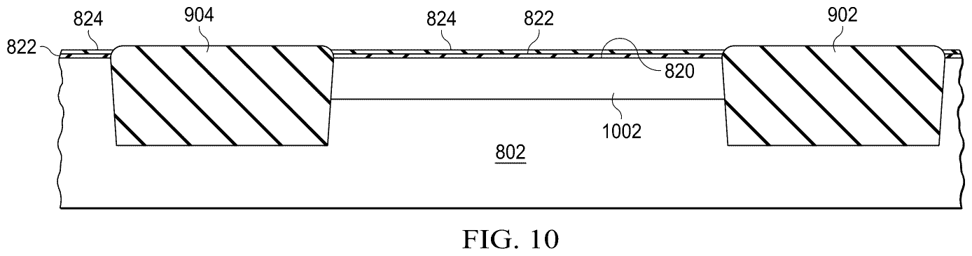

Referring to FIG. 10, an n-type doped sub-collector diffusion region 1002 is formed in the semiconductor substrate 802 laterally between the isolation structures 902, 904. The n-type doped sub-collector diffusion region 1002 may be formed by masking (e.g., by a photoresist using photolithography) areas of the semiconductor substrate 802 where an n-type doped sub-collector diffusion region is not to be formed and implanting n-type dopants into the semiconductor substrate 802. The n-type doped sub-collector diffusion region 1002 extends from the upper surface 820 of the semiconductor substrate 802 into a depth in the semiconductor substrate 802 and is laterally between the isolation structures 902, 904. A concentration of the n-type doped sub-collector diffusion region 1002 is greater than a concentration of the p-type dopant of the semiconductor substrate 802. In some examples, the n-type doped sub-collector diffusion region 1002 is doped with an n-type dopant with a concentration in a range from 1×10¹⁸ cm⁻³ to 1×10²⁰ cm⁻³. Another dopant and/or other doping concentrations may be implemented.

Although the semiconductor substrate 802 and n-type doped sub-collector diffusion region 1002 are described herein as being doped with a certain dopant conductivity type, such components may be doped with an opposite conductivity type (e.g., being n-type doped instead of p-type doped, and vice versa) in other examples. Similarly, subsequently described components that are described as being doped with a certain dopant conductivity type may also be doped with an opposite conductivity type in other examples.

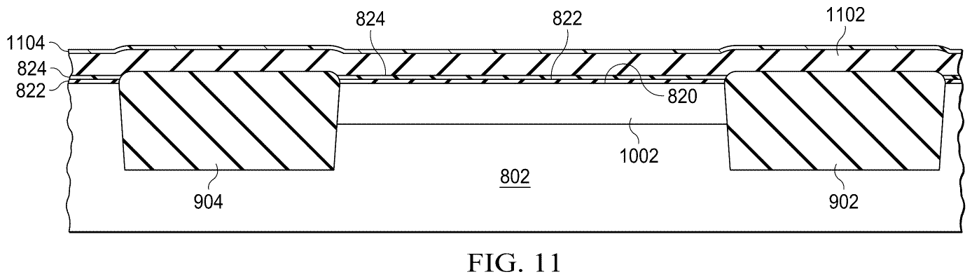

Referring to FIG. 11, a third pedestal dielectric sub-layer 1102 is formed over the second pedestal dielectric sub-layer 824 and the isolation structures 902, 904, and a hardmask layer 1104 is formed conformally over the third pedestal dielectric sub-layer 1102. The pedestal dielectric sub-layers 822, 824, 1102 form a pedestal dielectric stack that is pattered in subsequent processing. In some examples, the third pedestal dielectric sub-layer 1102 is silicon oxide (e.g., a TEOS oxide) deposited by CVD, although other dielectric materials and/or other deposition processes may be used in other examples. In some examples, the third pedestal dielectric sub-layer 1102 has an etch rate greater than respective etch rates of the first pedestal dielectric sub-layer 822 and second pedestal dielectric sub-layer 824. In some examples, the hardmask layer 1104 is or includes silicon nitride deposited by CVD, although other hardmask (e.g., dielectric) materials and/or other deposition processes may be used in other examples.

Referring to FIGS. 12 and 12A, a carbon hardmask layer 1202 formed over the hardmask layer 1104. An anti-reflection coating (ARC) layer 1204 is formed over the carbon hardmask layer 1202, and a patterned photoresist 1206 is formed over the ARC layer 1204. The ARC layer 1204 may be or include one layer or multiple sub-layers, which may be or include an inorganic hardmask material used in, e.g., a tri-layer patterning scheme or the like. The carbon hardmask layer 1202 and the ARC layer 1204 may be formed by using a spin-on coating process or the like. The photoresist 1206 is deposited (e.g., by spin-on) on or over the ARC layer 1204 and patterned using photolithography. The photoresist 1206 is patterned (e.g., using photolithography) to have an opening corresponding to a collector opening that is to be formed.

Using the patterned photoresist 1206 as a mask, an etch process is performed to remove portions of the ARC layer 1204, the carbon hardmask layer 1202, the hardmask layer 1104, the third pedestal dielectric sub-layer 1102, the second pedestal dielectric sub-layer 824, and the first pedestal dielectric sub-layer 822 to form a recess 1214. The recess 1214 generally laterally corresponds to a collector opening that is to be formed. The etch process may be as described above with respect to FIG. 2. A portion 1216 of the first pedestal dielectric sub-layer 822 remains underlying the recess 1214 and between the recess 1214 and the upper surface 820 of the semiconductor substrate 802. The recess 1214 in FIGS. 12 and 12A generally corresponds to the recess 204 of FIG. 2. Similarly, the dielectric layer 104 of FIG. 2 may be or include the first pedestal dielectric sub-layer 822, may be or include the pedestal dielectric sub-layers 822, 824, or may be or include the pedestal dielectric sub-layers 822, 824, 1102. Thereafter, any remaining photoresist 1206, ARC layer 1204, and/or carbon hardmask layer 1202 may be removed, such as by an ashing.

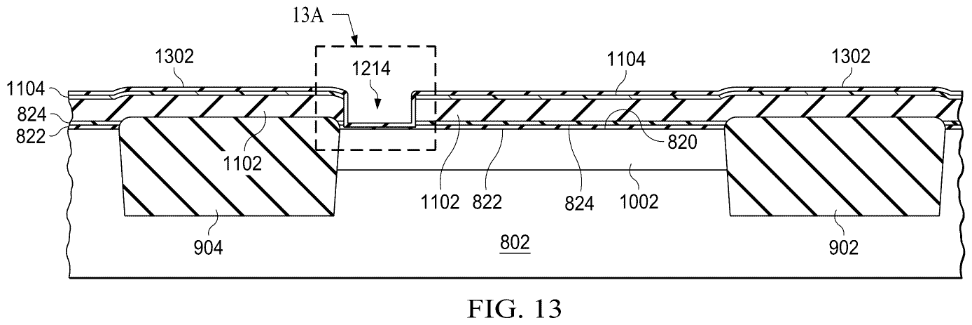

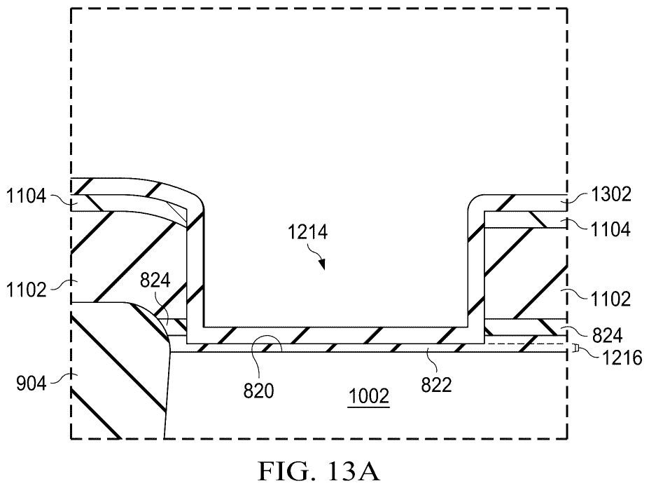

Referring to FIGS. 13 and 13A, a sidewall spacer layer 1302 is conformally formed over the hardmask layer 1104 and in the recess 1214. More specifically, the sidewall spacer layer 1302 is formed along respective sidewalls of the recess 1214 in the hardmask layer 106, pedestal dielectric sub-layers 822, 824, 1102, on a bottom surface of the recess 1214 in the first pedestal dielectric sub-layer 822, and on an upper surface of the hardmask layer 1104. As described with respect to FIG. 3, the sidewall spacer layer 1302 may be or include any dielectric material that has an etch rate to an etchant (e.g., that is used to etch a cavity as described below) that is less than an etch rate to the etchant of the first pedestal dielectric sub-layer 822 and/or second pedestal dielectric sub-layer 824. In some examples, a thickness of the sidewall spacer layer 1302 may be determined based on the etch rates to the etchant of the sidewall spacer layer 1302 and the first pedestal dielectric sub-layer 822 and/or second pedestal dielectric sub-layer 824 and a target profile of a cavity to be formed using an etch process that includes the etchant, as detailed subsequently. In some examples, the sidewall spacer layer 1302 is or includes silicon nitride and may be deposited by ALD, PECVD, or the like.

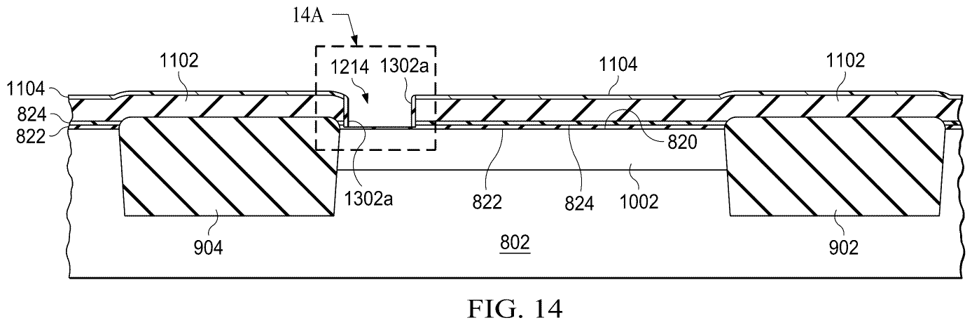

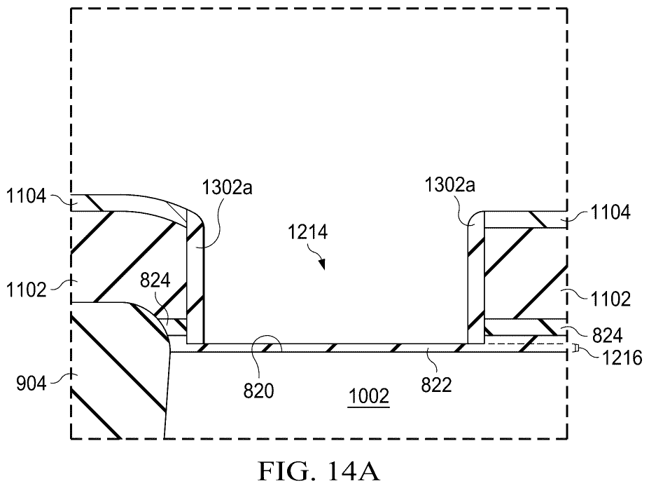

Referring to FIGS. 14 and 14A, sidewall spacers 1302a are formed along respective sidewalls of the recess 1214 from the sidewall spacer layer 1302. The sidewall spacers 1302a are formed along sidewalls of the pedestal dielectric sub-layers 822, 824, 1102 and the hardmask layer 1104. An anisotropic etch is performed to remove horizontal portions of the sidewall spacer layer 1302 such that vertical sidewall spacers 1302a remain on respective sidewalls of the recess 1214. The anisotropic etch may be an RIE, for example. The anisotropic etch removes the sidewall spacer layer 1302 from the upper surface of the hardmask layer 1104 and from the bottom surface of the recess 1214. The sidewall spacers 1302a may be formed as described above with respect to the sidewall spacers 302a in FIG. 4.

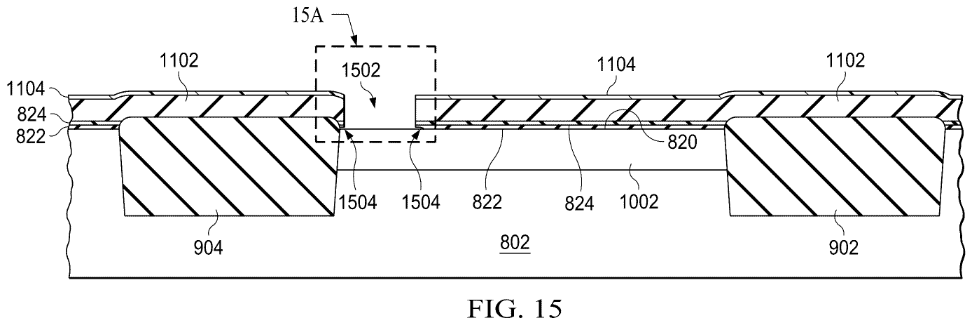

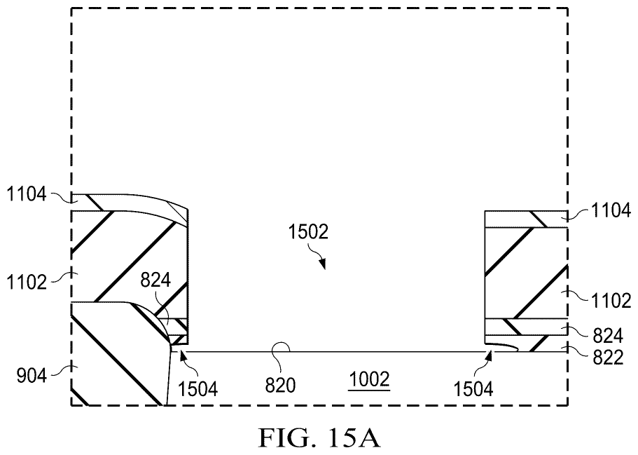

Referring to FIGS. 15 and 15A, an etch process is performed to remove the remaining portion 1216 of the first pedestal dielectric sub-layer 822 and to undercut in the first pedestal dielectric sub-layer 822 (and possibly, the second pedestal dielectric sub-layer 824) under the sidewall spacers 1302a. The process also consumes and removes the sidewall spacers 1302a. The etch process uses an etchant, and the etch rate of the sidewall spacers 1302a to the etchant is less than the etch rate(s) of the first and second pedestal dielectric sub-layers 822, 824 to the etchant. The etch process is as described above with respect to FIG. 5. Before the sidewall spacers 1302a are completely consumed by the etch process, the sidewall spacers 1302a prevent the sidewalls of the pedestal dielectric sub-layers 822, 824, 1102 from being etched where the sidewall spacers 1302a cover the sidewalls. The etch removes the remaining portion 1216 of the first pedestal dielectric sub-layer 822 from the bottom surface of the recess 1214 to expose the upper surface 820 of the semiconductor substrate 802. As the etch is performed, cavities 1504 are isotropically formed in the first pedestal dielectric sub-layer 822 undercutting the sidewall spacers 1302a. The cavities 1504 are formed to and expose the upper surface 820 of the semiconductor substrate 802. The etch forms a collector opening 1502 through the pedestal dielectric stack (e.g., the pedestal dielectric sub-layers 822, 824, 1102), and the collector opening 1502 is laterally defined by the sidewalls corresponding to the recess 1214 (e.g., sidewalls of the hardmask layer 1104 and the pedestal dielectric sub-layers 822, 824, 1102) and curved surfaces of cavities 1504 in the first pedestal dielectric sub-layer 822. The collector opening 1502 is generally proximate to (or some lateral distance from) the isolation structure 904 and over the n-type doped sub-collector diffusion region 1002. The cavities 1504 of FIGS. 15 and 15A are like the cavities 504 of FIG. 5.

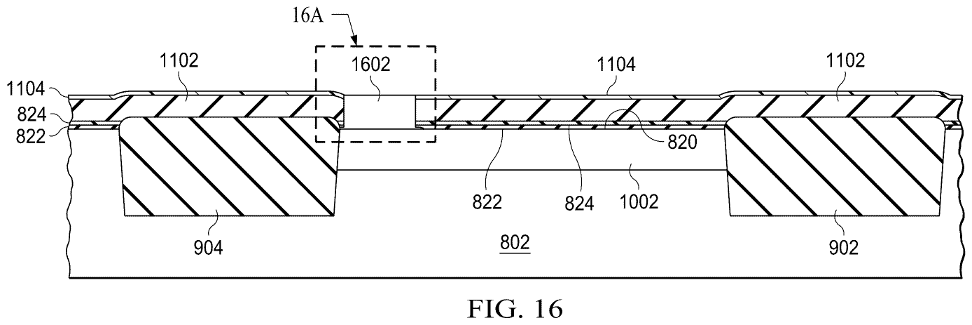

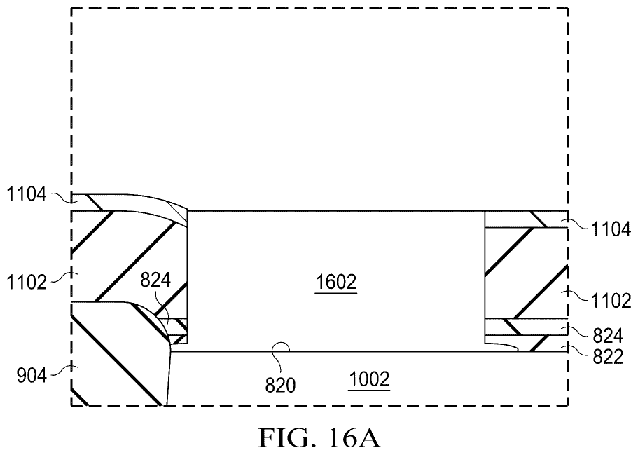

Referring to FIGS. 16 and 16A, a collector layer 1602 is formed over (e.g., on) the upper surface 820 of the semiconductor substrate 802 and in the collector opening 1502. In some examples, the collector layer 1602 is or includes a semiconductor layer doped with an n-type dopant (e.g., a same dopant type as the n-type doped sub-collector diffusion region 1002). In some examples, the collector layer 1602 is or includes silicon. In some examples, the collector layer 1602 is doped with an n-type dopant with a concentration in a range from 1×10¹⁹ cm⁻³ to 1×10²¹ cm⁻³. The collector layer 1602 may be epitaxially grown on the upper surface 820 of the semiconductor substrate 802 like described above with respect to the epitaxial layer 602, 702 in FIGS. 6 and 7. Like described above with respect to FIG. 6, the epitaxial growth of the collector layer 1602 forms an upper surface that replicates the upper surface 820 of the semiconductor surface and may form a facet. For example, the upper surface of the collector layer 1602 may be a (100) plane when the upper surface 820 of the semiconductor substrate 802 is a (100) plane, and the facet may be in a (111) plane. The facet may meet the curved surface of the cavity 1504 at an intersection point, and the curved surface of the cavity 1504 meeting the facet arrests the facet and prevents the facet from propagating in subsequent epitaxial growth. Hence, the upper surface of the collector layer 1602 may continue to be replicated vertically in subsequent epitaxial growth without the facet meeting and laterally limiting replication of the upper surface. The collector layer 1602 may be epitaxially grown by a selective epitaxial growth process in some examples. The epitaxial growth of the collector layer 1602 on the upper surface 820 of the semiconductor substrate 802 may result in the collector layer 1602 being monocrystalline. Further, the collector layer 1602 may be in situ doped during the epitaxial growth process (e.g., the selective epitaxial growth process). The epitaxial growth process may be a CVD process, such as an LPCVD, RPCVD, MOCVD, or the like. Other materials, dopant type, dopant concentration, and/or deposition process may be implemented.

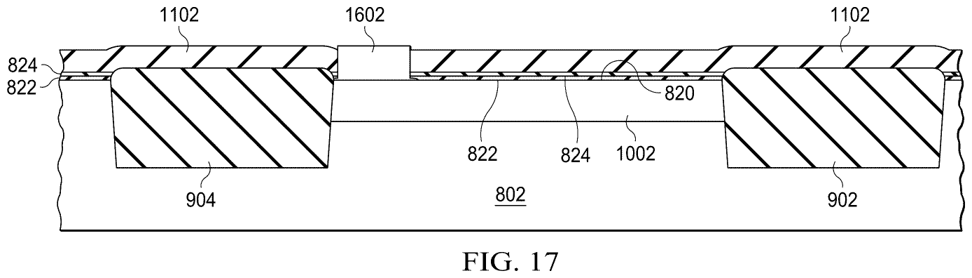

Referring to FIG. 17, the hardmask layer 1104 is removed. The hardmask layer 1104 may be removed using an etch selective to the material of the hardmask layer 1104. The etch process may be a wet or dry etch process and may be isotropic. For example, when the hardmask layer 1104 is silicon nitride, the etch process may be or include using phosphoric acid.

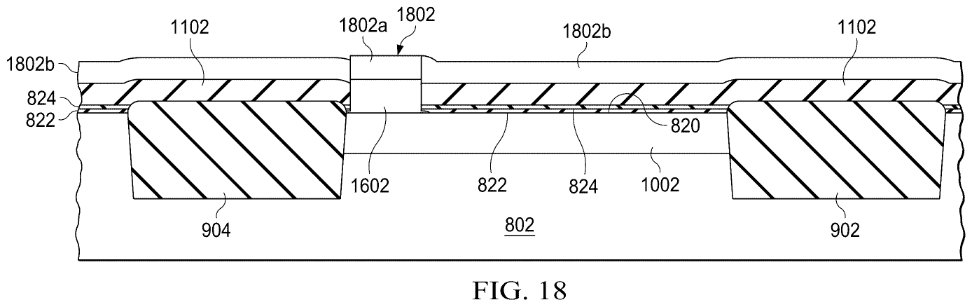

Referring to FIG. 18, a base layer 1802 is formed over the collector layer 1602. The base layer 1802 includes a monocrystalline base layer 1802a and a polycrystalline base layer 1802b. The monocrystalline base layer 1802a and polycrystalline base layer 1802b together form the base layer 1802. In some examples, the base layer 1802 is or includes a semiconductor layer doped with a p-type dopant (e.g., an opposite dopant type as the collector layer 1602). In some examples, the base layer 1802 is or includes silicon germanium. In some examples, the base layer 1802 is doped with a p-type dopant with a concentration in a range from 1×10¹⁷ cm⁻³ to 1×10²¹ cm⁻³. The base layer 1802 may also be doped with carbon (C) to prevent or reduce diffusion of the p-type dopant. The base layer 1802 may be epitaxially grown on the collector layer 1602 and conformally on the third pedestal dielectric sub-layer 1102. The base layer 1802 may be epitaxially grown by a non-selective epitaxial growth process in some examples. The non-selective epitaxial growth process grows the monocrystalline base layer 1802a from the collector layer 1602 and grows the polycrystalline base layer 1802b on other amorphous or polycrystalline surfaces, such as the third pedestal dielectric sub-layer 1102. The monocrystalline base layer 1802a may meet the polycrystalline base layer 1802b at a facet that is not specifically illustrated. The non-selective deposition of the base layer 1802 forms the base layer 1802 conformally. The base layer 1802 may be in situ doped during the epitaxial growth process. The base layer 1802 (e.g., the monocrystalline base layer 1802a and polycrystalline base layer 1802b each) may further include multiple sub-layers, such as a nucleation sub-layer of the same material as the collector layer 1602, an undoped sub-layer, a doped sub-layer, and a cap sub-layer of the same material of the emitter layer (described subsequently). The epitaxial growth process may be a CVD process, such as LPCVD, RPCVD, MOCVD, or the like. Other materials, dopant type, dopant concentration, and/or deposition process may be implemented.

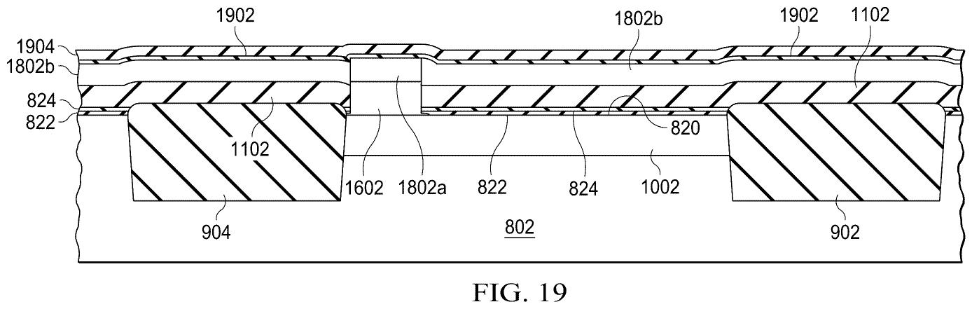

Referring to FIG. 19, a first dielectric spacer layer 1902 is formed conformally over the base layer 1802, and a second dielectric spacer layer 1904 is formed conformally over the first dielectric spacer layer 1902. In some examples, the second dielectric spacer layer 1904 is a dielectric material different from the dielectric material of the first dielectric spacer layer 1902. In some examples, the first dielectric spacer layer 1902 is silicon oxide (e.g., a TEOS oxide), and the second dielectric spacer layer 1904 is silicon nitride. The dielectric spacer layers 1902, 1904 may be deposited by CVD. Other dielectric materials and/or other deposition processes may be used in other examples.

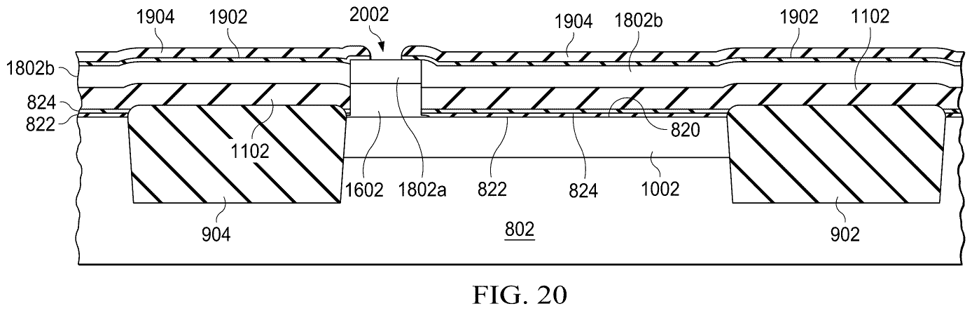

Referring to FIG. 20, the dielectric spacer layers 1902, 1904 are etched to form an emitter opening 2002 through the first dielectric spacer layer 1902 and the second dielectric spacer layer 1904. The monocrystalline base layer 1802a (of the base layer 1802) is exposed through the emitter opening 2002. The dielectric spacer layers 1902, 1904 may be patterned using appropriate photolithography and etch (e.g., RIE) processes.

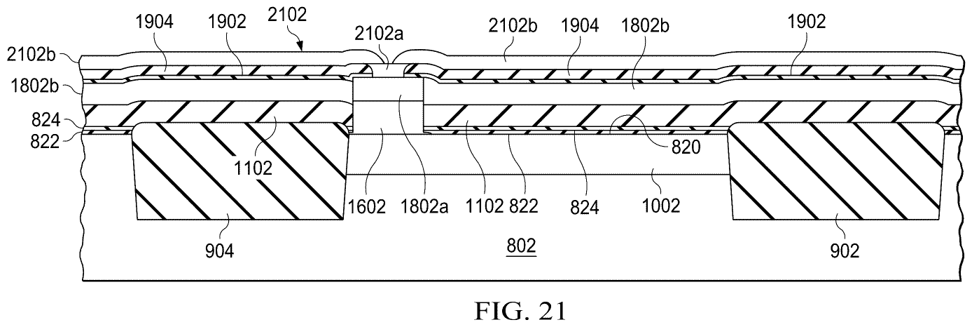

Referring to FIG. 21, an emitter layer 2102 is formed over the base layer 1802 (e.g., on the monocrystalline base layer 1802a). The emitter layer 2102 includes a monocrystalline emitter layer 2102a and a polycrystalline emitter layer 2102b. The monocrystalline emitter layer 2102a and polycrystalline emitter layer 2102b together form the emitter layer 2102. In some examples, the emitter layer 2102 is or includes a semiconductor layer doped with an n-type dopant (e.g., an opposite dopant type from the base layer 1802). In some examples, the emitter layer 2102 is or includes silicon. In some examples, the emitter layer 2102 is doped with an n-type dopant with a concentration in a range from 1×10¹⁹ cm⁻³ to 1×10²¹ cm⁻³. The emitter layer 2102 may be epitaxially grown on the base layer 1802 (e.g., the monocrystalline base layer 1802a) exposed through the emitter opening 2002 and on the second dielectric spacer layer 1904. The emitter layer 2102 may be epitaxially grown by a non-selective epitaxial growth process in some examples. The non-selective epitaxial growth process grows the monocrystalline emitter layer 2102a from the monocrystalline base layer 1802a and grows the polycrystalline emitter layer 2102b on other amorphous or polycrystalline surfaces, such as the second dielectric spacer layer 1904. The monocrystalline emitter layer 2102a may meet the polycrystalline emitter layer 2102b at a facet that is not specifically illustrated. The non-selective deposition of the emitter layer 2102 forms the emitter layer 2102 conformally. The emitter layer 2102 may be in situ doped during the epitaxial growth process. The epitaxial growth process may be a CVD process, such as LPCVD, RPCVD, MOCVD, or the like. Other materials, dopant type, dopant concentration, and/or deposition process may be implemented.

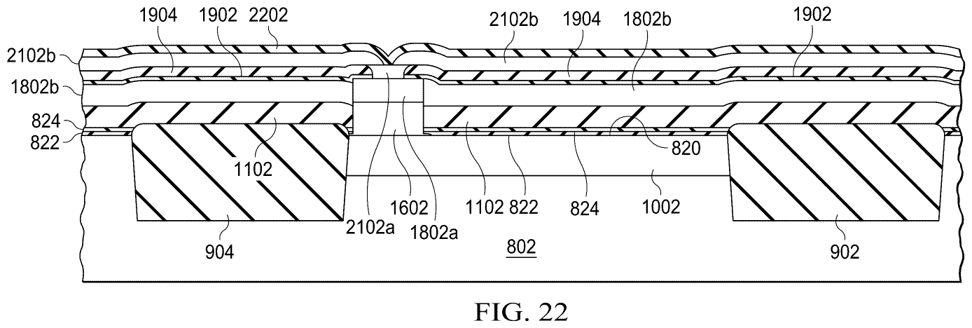

Referring to FIG. 22, an emitter dielectric cap layer 2202 is conformally formed over the emitter layer 2102. In some examples, the emitter dielectric cap layer 2202 is silicon oxide (e.g., a TEOS oxide) deposited by CVD, although other dielectric materials and/or other deposition processes may be used in other examples.

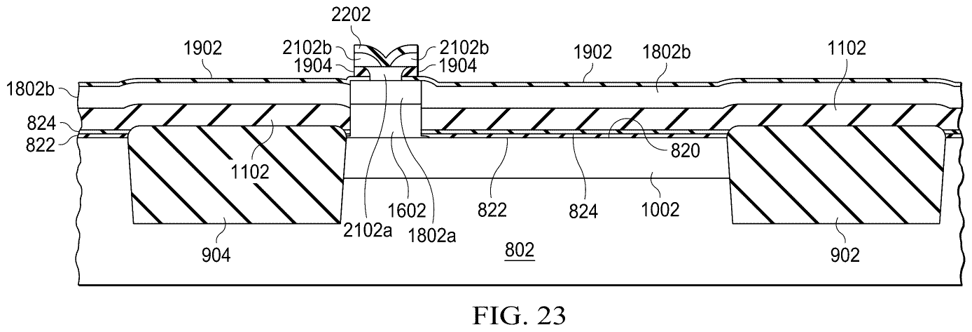

Referring to FIG. 23, the emitter dielectric cap layer 2202, polycrystalline emitter layer 2102b, and second dielectric spacer layer 1904 are patterned. In the illustrated example, the layers 2202, 2102b, 1904 are patterned using appropriate photolithography and etch (e.g., anisotropic etch, such as RIE) processes.

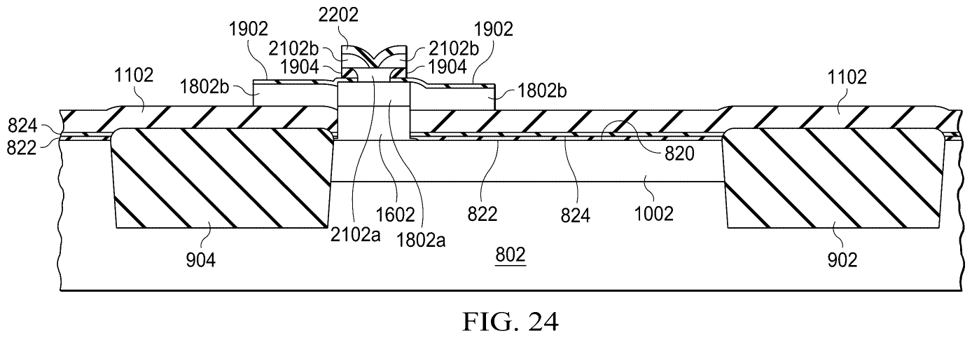

Referring to FIG. 24, the first dielectric spacer layer 1902 and the base layer 1802 (e.g., the polycrystalline base layer 1802b) are patterned. In some examples, the third pedestal dielectric sub-layer 1102 may be thinned in areas where the first dielectric spacer layer 1902 and the polycrystalline base layer 1802b are removed. The first dielectric spacer layer 1902 and the polycrystalline base layer 1802b may be patterned using appropriate photolithography and etch (e.g., RIE) processes.

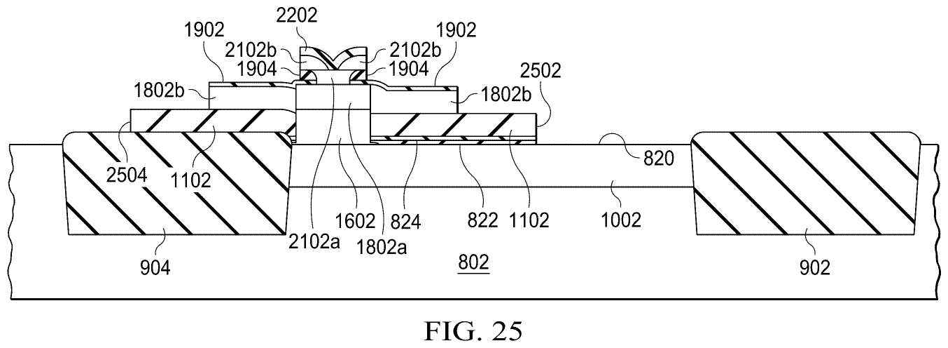

Referring to FIG. 25, the third pedestal dielectric sub-layer 1102, the second pedestal dielectric sub-layer 824, and the first pedestal dielectric sub-layer 822 are patterned. Patterning the pedestal dielectric sub-layers 822, 824, 1102 forms the pedestal dielectric stack (e.g., the third pedestal dielectric sub-layer 1102) with sidewalls 2502, 2504. The sidewall 2502 of the pedestal dielectric stack (e.g., the pedestal dielectric sub-layers 822, 824, 1102) is over the upper surface 820 of the semiconductor substrate 802 and the n-type doped sub-collector diffusion region 1002. The sidewall 2504 of the pedestal dielectric stack (e.g., the third pedestal dielectric sub-layer 1102) is over the isolation structure 904. Portions of the pedestal dielectric sub-layers 822, 824, 1102 are removed from over at least a portion of the n-type doped sub-collector diffusion region 1002. The pedestal dielectric sub-layers 822, 824, 1102 may be patterned using appropriate photolithography and etch (e.g., RIE) processes.

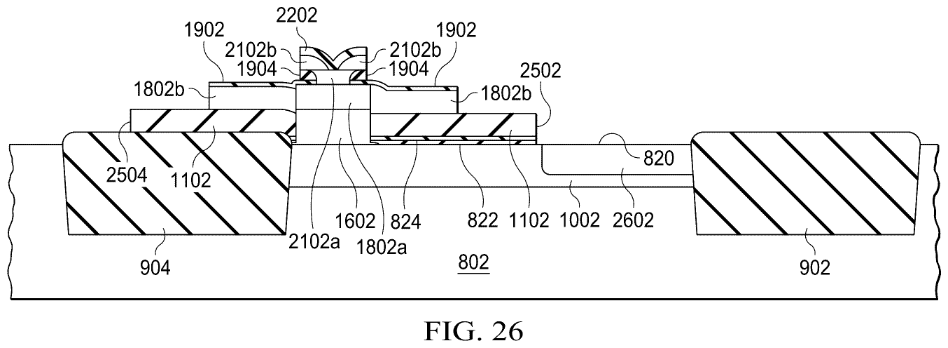

Referring to FIG. 26, an n-type collector contact region 2602 is formed in the semiconductor substrate 802. The n-type collector contact region 2602 is formed in the n-type doped sub-collector diffusion region 1002 in the semiconductor substrate 802. The n-type collector contact region 2602 is laterally between the pedestal dielectric stack (e.g., the pedestal dielectric sub-layers 822, 824, 1102) and the isolation structure 902. An implantation is performed to form the n-type collector contact region 2602. The n-type collector contact region 2602 may be formed by masking (e.g., by a photoresist using photolithography) the base layer 1802 and emitter layer 2102 and implanting an n-type dopant into the semiconductor substrate 802 in an exposed portion of the semiconductor substrate 802 corresponding to the n-type collector contact region 2602. A concentration of the n-type dopant of the n-type collector contact region 2602 is greater than the concentration of the n-type dopant of the n-type doped sub-collector diffusion region 1002. In some examples, the n-type collector contact region 2602 is doped with an n-type dopant with a concentration in a range from 1×10²⁰ cm⁻³ to 1×10²¹ cm⁻³. Other doping concentrations may be implemented.

Referring to FIG. 27, metal-semiconductor compound 2702, 2704, 2706 are formed. The metal-semiconductor compound 2702 is on the emitter layer 2102 (e.g., the polycrystalline emitter layer 2102b and/or monocrystalline emitter layer 2102a). The metal-semiconductor compound 2704 is on the base layer 1802 (e.g., the polycrystalline base layer 1802b). The metal-semiconductor compound 2706 is on the upper surface 820 of the semiconductor substrate 802 at the n-type collector contact region 2602. The metal-semiconductor compound 2702, 2704, 2706 may be a silicide (e.g., NiSix, TiSix, CoSix, PtSix), a germanicide, or the like.

To form the metal-semiconductor compound 2702, 2704, 2706, any remaining dielectric material on surfaces on which the metal-semiconductor compound 2702, 2704, 2706 are to be formed is removed. For example, the emitter dielectric cap layer 2202 and exposed portions of the first dielectric spacer layer 1902 may be removed by an etch and/or cleaning process. For example, when the emitter dielectric cap layer 2202 and the first dielectric spacer layer 1902 are silicon oxide, dilute hydrochloric acid (dHCl) may be used. The first dielectric spacer layer 1902 underlying the second dielectric spacer layer 1904 remains after the exposed portions of the first dielectric spacer layer 1902 are removed. Other layers may be thinned by the etch and/or cleaning process. For example, exposed portions of the third pedestal dielectric sub-layer 1102 may be thinned.

The metal-semiconductor compound 2702, 2704, 2706 may then be formed by depositing a metal (e.g., Ni, Ti, Co, Pt) over the semiconductor substrate 802, such as by physical vapor deposition (PVD), CVD, or the like. The metal is reacted with a semiconductor material, such as the semiconductor material of the emitter layer 2102 (e.g., polycrystalline emitter layer 2102b and/or monocrystalline emitter layer 2102a), the semiconductor material of the base layer 1802 (e.g., the polycrystalline base layer 1802b and/or monocrystalline base layer 1802a), and the semiconductor material of the semiconductor substrate 802. An anneal process may be used to cause the metal to react with a semiconductor material. For example, a laser anneal (e.g., a millisecond laser anneal) may be used in a reduced thermal budget implementation. Any unreacted metal may be removed, such as by an etch selective to the metal.

After forming the metal-semiconductor compound 2702, 2704, 2706, a dielectric layer 2712 is formed over the semiconductor substrate 802, and contacts 2722, 2724, 2726 are formed through the dielectric layer 2712. The dielectric layer 2712 may include one or more dielectric sub-layers. For example, the dielectric layer 2712 may include a conformal first dielectric sub-layer over the semiconductor substrate 802 and a second dielectric sub-layer over the first dielectric sub-layer. The conformal first dielectric sub-layer may be a stressor layer, an etch stop layer, or the like, which may be or include silicon nitride, silicon oxynitride, the like, or a combination thereof. The second dielectric sub-layer may be or include silicon oxide, silicon nitride, or the like. The dielectric layer 2712 may be or include a pre-metal dielectric (PMD), an inter-layer dielectric (ILD), or the like. The dielectric layer 2712 may be deposited using CVD, PECVD, ALD, or the like. The dielectric layer 2712 may be planarized, such as by a CMP.

The contacts 2722, 2724, 2726 extend through the dielectric layer 2712 and contact respective metal-semiconductor compound 2702, 2704, 2706. The contacts 2722, 2724, 2726 may each include one or more barrier and/or adhesion layers (e.g., titanium nitride (TiN), tantalum nitride (TaN), the like, or a combination thereof) conformally in a respective opening through the dielectric layer 2712, and a fill metal (e.g., tungsten (W), copper (Cu), aluminum (Al), the like, or a combination thereof) over and/or on the barrier and/or adhesion layer(s). To form the contacts 2722, 2724, 2726, respective openings may be formed through the dielectric layer 2712 to the metal-semiconductor compound 2702, 2704, 2706 using appropriate photolithography and etching processes. A metal(s) of the contacts 2722, 2724, 2726 are deposited in the openings through the dielectric layer 2712. The metal(s) may be deposited using an appropriate deposition process(es), such as CVD, PVD, or the like. Any excess metal(s) may be removed, such as by a CMP and/or by patterning using photolithography and etch processes.

FIG. 27 illustrates a semiconductor device 2700. The semiconductor device 2700 is or includes a BJT. The BJT includes the collector layer 1602, base layer 1802 (e.g., monocrystalline base layer 1802a and polycrystalline base layer 1802b), and emitter layer 2102 (e.g., monocrystalline emitter layer 2102a and polycrystalline emitter layer 2102b).

The collector layer 1602 is over and on the upper surface 820 of the semiconductor substrate 802 and is through an opening in a pedestal dielectric stack (e.g., the third pedestal dielectric sub-layer 1102, second pedestal dielectric sub-layer 824, and first pedestal dielectric sub-layer 822), which is also over the upper surface 820 of the semiconductor substrate 802. The collector layer 1602 is on the n-type doped sub-collector diffusion region 1002 in the semiconductor substrate 802. The base layer 1802 (e.g., the monocrystalline base layer 1802a) is over and on the collector layer 1602, and the base layer 1802 (e.g., the polycrystalline base layer 1802b) is over and on an upper surface of the pedestal dielectric stack (e.g., the third pedestal dielectric sub-layer 1102).

The pedestal dielectric stack (e.g., the pedestal dielectric sub-layers 822, 824, 1102) underlies the base layer 1802. The pedestal dielectric stack extends laterally from the base layer 1802 (e.g., the polycrystalline base layer 1802b). For example, the pedestal dielectric stack extends over and on the upper surface 820 of the semiconductor substrate 802 over the n-type doped sub-collector diffusion region 1002 and laterally away from a corresponding sidewall of the polycrystalline base layer 1802b to the sidewall 2502 proximate the n-type collector contact region 2602. Additionally, the pedestal dielectric stack (e.g., the third pedestal dielectric sub-layer 1102) extends over and on the isolation structure 904 laterally away from a corresponding sidewall of the polycrystalline base layer 1802b to the sidewall 2504 over the isolation structure 904.

The emitter layer 2102 (e.g., the monocrystalline emitter layer 2102a) is over and on the base layer 1802 (e.g., the monocrystalline base layer 1802a) and is through an opening defined by a spacer structure, and the emitter layer 2102 (e.g., the polycrystalline emitter layer 2102b) is over and on the spacer structure. The spacer structure includes the first dielectric spacer layer 1902 and the second dielectric spacer layer 1904.

The metal-semiconductor compound 2702 is on the emitter layer 2102 (e.g., the polycrystalline emitter layer 2102b and/or monocrystalline emitter layer 2102a). The metal-semiconductor compound 2704 is on the base layer 1802 (e.g., the polycrystalline base layer 1802b). The metal-semiconductor compound 2706 is on the upper surface 820 of the semiconductor substrate 802 on the n-type collector contact region 2602.

In some examples, the BJT may be a heterojunction BJT. As indicated previously, in some examples, the collector layer 1602 and the emitter layer 2102 may be silicon, and the base layer 1802 may include silicon germanium. Hence, in some examples, the base layer 1802 may include a semiconductor material dissimilar from respective semiconductor materials of the collector layer 1602 and emitter layer 2102. The dissimilar semiconductor materials may form one or more heterojunctions in the BJT, and the BJT may therefore be a heterojunction BJT.

Although various examples have been described in detail, it should be understood that various changes, substitutions, and alterations can be made therein without departing from the scope defined by the appended claims.

What is claimed is:

1. A method, comprising:
forming a dielectric layer over a first semiconductor material, the first semiconductor material comprising a monocrystalline surface;
forming a recess in the dielectric layer, the recess being defined at least in part by a recess sidewall of the dielectric layer;
forming a spacer layer conformally in the recess;
forming a sidewall spacer in the recess from the spacer layer, the sidewall spacer being along the recess sidewall;
forming an opening through the dielectric layer to the monocrystalline surface, forming the opening including etching the dielectric layer under the sidewall spacer, the opening being defined at least in part by an opening sidewall of the dielectric layer and a cavity in the dielectric layer, the opening sidewall corresponding to the recess sidewall, the cavity being at the monocrystalline surface and under the opening sidewall; and
forming a second semiconductor material over the first semiconductor material and on the monocrystalline surface, the second semiconductor material being at least partially in the opening through the dielectric layer.

2. The method of claim 1, wherein forming the opening includes using an etch process that uses an etchant, an etch rate to the etchant of the dielectric layer being greater than an etch rate to the etchant of the sidewall spacer.

3. The method of claim 2, wherein the etch process that uses the etchant is an isotropic etch process.

4. The method of claim 2, wherein the etch process that uses the etchant is a wet etch process.

5. The method of claim 1, wherein forming the opening includes using an etch process that uses an etchant, wherein the etchant in the etch process removes the sidewall spacer and forms the cavity.

6. The method of claim 1, wherein:
the dielectric layer includes silicon oxide;
the sidewall spacer includes silicon nitride; and
forming the opening includes using an etch process that uses an etchant, the etchant including hydrofluoric acid.

7. The method of claim 1, wherein forming the recess in the dielectric layer includes using a photoresist over the dielectric layer, the photoresist being removed before forming the spacer layer.

8. The method of claim 1, wherein forming the sidewall spacer in the recess from the spacer layer includes anisotropically etching the spacer layer.

9. The method of claim 1, wherein forming the second semiconductor material includes epitaxially growing the second semiconductor material on the monocrystalline surface.

10. The method of claim 9, wherein epitaxially growing the second semiconductor material on the monocrystalline surface forms a facet of the second semiconductor material, the facet being trapped in the cavity in the dielectric layer.

11. The method of claim 1, wherein the cavity in the dielectric layer is configured to trap a facet of the second semiconductor material in the cavity.

12. The method of claim 1, wherein the cavity has a surface that meets the opening sidewall at a first intersection and meets the monocrystalline surface at a second intersection, a line through the first intersection and the second intersection forming an angle with the monocrystalline surface laterally interior to the opening, the angle being equal to or less than 54 degrees.

13. The method of claim 1, wherein the cavity has a surface that meets the opening sidewall at a first intersection and meets the monocrystalline surface at a second intersection, a vertical dimension being vertically from the monocrystalline surface to the first intersection, a lateral dimension being laterally from the first intersection to the second intersection, a ratio of the vertical dimension to the lateral dimension being equal to or less than 1.376.

14. A method, comprising:
forming a pedestal dielectric stack over a semiconductor substrate;
forming a recess in the pedestal dielectric stack, the recess being defined at least in part by a recess sidewall of the pedestal dielectric stack;
forming a spacer layer over the pedestal dielectric stack and conformally in the recess;
anisotropically etching the spacer layer to form a sidewall spacer on the recess sidewall;
isotropically etching the pedestal dielectric stack through the recess, wherein isotropically etching the pedestal dielectric stack forms an opening through the pedestal dielectric stack to the semiconductor substrate, the opening being defined at least in part by an opening sidewall of the pedestal dielectric stack and a cavity in the pedestal dielectric stack under the opening sidewall, the opening sidewall corresponding to the recess sidewall; and
forming a bipolar junction transistor (BJT) on the semiconductor substrate, at least a portion of the BJT being in the opening and on the semiconductor substrate.

15. The method of claim 14, wherein isotropically etching the pedestal dielectric stack uses an etchant, an etch rate of the sidewall spacer to the etchant being less than an etch rate of the pedestal dielectric stack to the etchant.

16. The method of claim 14, wherein isotropically etching the pedestal dielectric stack removes the sidewall spacer from the recess sidewall.

17. The method of claim 14, wherein forming the recess in the pedestal dielectric stack includes using a photoresist over the pedestal dielectric stack, the photoresist being removed before forming the spacer layer.

18. The method of claim 14, wherein forming the BJT includes epitaxially growing a collector layer of the BJT in the opening on the semiconductor substrate.

19. The method of claim 14, wherein the cavity has a surface that meets the opening sidewall at a first intersection and meets an upper surface of the semiconductor substrate at a second intersection, a line through the first intersection and the second intersection forming an angle with the upper surface laterally interior to the opening, the angle being equal to or less than 54 degrees.

20. The method of claim 14, wherein the cavity has a surface that meets the opening sidewall at a first intersection and meets an upper surface of the semiconductor substrate at a second intersection, a vertical dimension being vertically from the upper surface to the first intersection, a lateral dimension being laterally from the first intersection to the second intersection, a ratio of the vertical dimension to the lateral dimension being equal to or less than 1.376.
